(19) United States
(12) Patent Application Publication
(10) Pub. No.: US 2009/0123789 A1
(43) Pub. Date: May 14, 2009

(54) METHODS OF GAS CONFINEMENT WITHIN THE VOIDS OF CRYSTALLINE MATERIAL AND ARTICLES THEREOF

(75) Inventors: William K. Cooper, Santa Fe, NM (US); James F. Loan, Bellows Falls, VT (US); Christopher H. Cooper, Windsor, VT (US)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Seldon Technologies, LLC

(21) Appl. No.: 12/118,495

(22) Filed: May 9, 2008

Related U.S. Application Data
(60) Provisional application No. 60/924,376, filed on May 10, 2007.

(51) Int. Cl. H01M 8/04; C09K 3/00; B32B 1/00; C23C 14/34; C25D 3/56; C25D 3/60; C25D 3/50; C25D 3/12; C25D 3/04; C25D 3/54; C25D 3/22; C25D 3/34; C25D 3/38; C25D 3/20; C25D 3/48; C25D 3/46; C25D 3/62; C25D 3/58; C25B 9/00; B05D 1/00; B82B 3/00; B82B 1/00

(52) U.S. Cl. 429/13; 252/188.25; 428/34.1; 427/220; 427/569; 204/450; 204/192.15; 205/239; 205/243; 205/244; 205/247; 205/252; 205/255; 205/263; 205/265; 205/264; 205/266; 205/269; 205/270; 205/271; 205/281; 205/283; 205/291; 205/299; 205/305; 205/315; 376/323; 977/742; 977/962

(57) ABSTRACT

There is disclosed articles for and methods of confining volatile materials in the void volume defined by crystalline void materials. In one embodiment, the hydrogen isotopes are confined inside carbon nanotubes for storage and the production of energy. There is also disclosed a method of generating various reactions by confining the volatile materials inside the crystalline void structure and releasing the confined volatile material. In this embodiment, the released volatile material may be combined with a different material to initiate or sustain a chemical, thermal, nuclear, electrical, mechanical, or biological reaction.

This application is based on and claims the benefit of U.S. Provisional Application No. 60/924,376, filed May 10, 2007, the contents of which are herein incorporated by reference in their entirety.

Disclosed herein are articles for, and methods of confining gas within the voids of crystalline material, such as the high pressure storage of hydrogen inside structures substantially comprised of crystalline carbon. The crystalline carbon structure that may be used according to the present disclosure may be a closed ended tube, such as a capped carbon nanotube. Also disclosed are methods of charging and discharging the crystalline material disclosed herein.

A need exists for alternative energy sources to alleviate our society's current dependence on hydrocarbon fuels without further impact to the environment. Devices powered with hydrogen sequestered safely at high pressure may be used for fuel cells to power cars, trucks, aircraft and almost any other system requiring the use of a load, such as information systems, lights and motors. For example, high energy density hydrogen fuel cell power systems may reduce, if not eliminate, the need for power distribution networks, standard chemical, batteries, hydrocarbon fuels, internal combustion, chemical rocket, or turbine engines, as well as all other forms of hydrocarbon chemical combustion for the production of power.

The inventors have developed multiple uses for novels forms of crystalline graphene rolled into cylindrical structures with internal volume that can be used to confine hydrogen at high pressures, such as in the mega-bar range. For example, carbon nanotubes due to their single crystalline nature, their hollow interior, their unique tensile and burst strength, may be used as the single crystalline void structure to confine hydrogen at high pressure.

Thus, the present disclosure combines the unique properties of high strength and low diffusivity of crystalline materials, such as carbon nanotubes, to confine fluids, such as volatile materials, including hydrogen, at elevated pressures. The disclosed method may substantially change the current state of power distribution, and thus meet current and future energy needs in an environmentally friendly way.

### SUMMARY OF THE INVENTION

Accordingly, there is disclosed a method for the sequestering of volatile materials, which comprises the confinement of a fluid and/or gas inside a void of substantially single crystalline material. In one embodiment, the gases are comprised of hydrogen isotopes, oxygen isotopes, or other oxidizing agents and combinations thereof. In addition, the source of hydrogen isotopes may be in a solid, liquid, gas, plasma, supercritical phase. Alternatively, the source of hydrogen isotopes may be bound in a molecular structure.

There is also disclosed a method of releasing gas from the crystalline voids for consumption, such as the release of hydrogen for combustion with oxygen in a fuel cell. Alternatively, the hydrogen may be consumed within the crystalline void structure resulting in the release of energy. Furthermore the hydrogen isotopes of deuterium and tritium may be confined in the crystalline void structure to be utilized in the production of nuclear fusion energy.

There is also disclosed an article for the confinement of a fluid comprising one or more voids in a crystalline structure for confining fluid, wherein a majority of the voids have as a smallest dimension of one micron or less, such as 100 nm or less.

### BRIEF DESCRIPTION OF THE DRAWINGS

FIG. 1 is a schematic drawing of void in a crystalline material with/without confined fluid according to the present disclosure.

FIG. 2 is a schematic drawing of void in crystalline quartz for the confinement of hydrogen isotopes with palladium valve structures according to the present disclosure.

FIG. 3 is a schematic drawing of channel in tubular graphene crystalline material for the confinement of hydrogen isotopes with palladium valve structures according to the present disclosure.

FIG. 4 is a schematic drawing of carbon nanotube palladium end-cap lamination for the ion implantation and pressurization of hydrogen isotopes inside the channel according to the present disclosure.

FIG. 5 is a schematic drawing of the system for carbon nanotube palladium end-cap lamination wired to an electronics package for the cathodic charging and pressurization of hydrogen isotopes inside the channel for hydrogen fusion reaction according to the present disclosure.

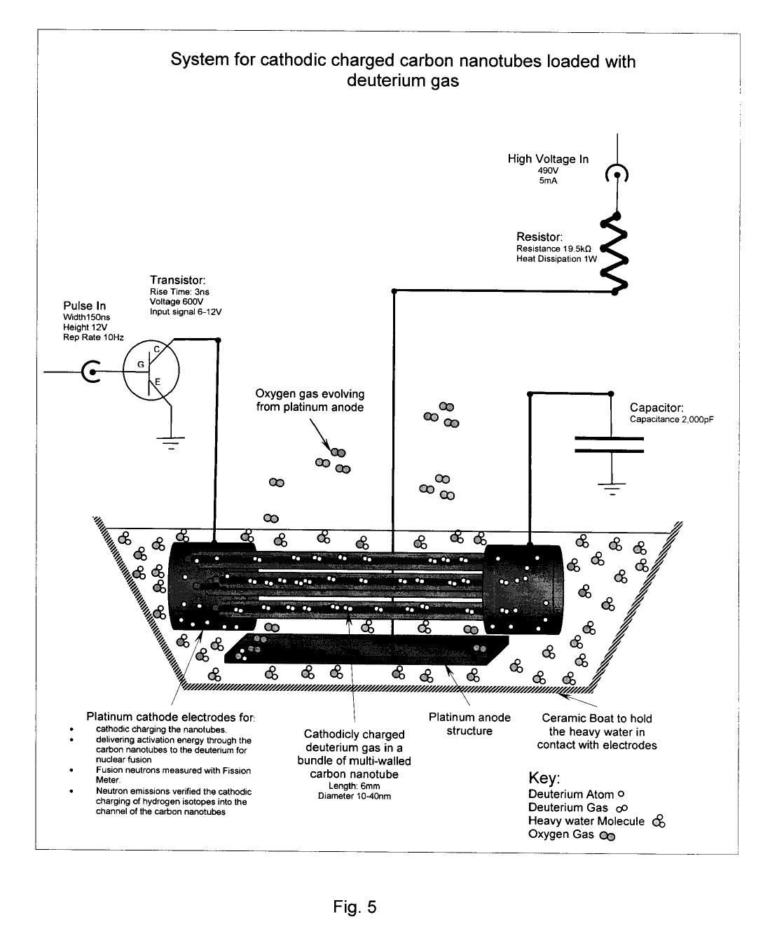

### DETAILED DESCRIPTION OF THE INVENTION

### A. Definitions

The following terms or phrases used in the present disclosure have the meanings outlined below:

The phrase “crystalline void structure” refers to a structure that is substantially comprised of crystalline structure further containing at least one element that acts as a valve sufficient to confine and allow gas to transfer therethrough.

The phrase “crystalline material” refers to a solid in which the constituent atoms, molecules, or ions are packed in a regularly ordered, repeating pattern extending in all three spatial dimensions, sometimes referred to as a unit cell. Under this definition, one or few graphitic layers are also be defined as “crystalline material”. Carbon nanotubes and nanohorns are made from one or few graphitic layers with specific symmetrical operation are also defined as “crystalline material”. Carbon fullerene, because of its perfect symmetrical structure, is also defined as crystalline material. Further more, nanotubes, nanohores and fullerenes made out from other inorganic crystalline materials could also be defined as crystalline materials.

The term “void” refers to a bulk defect in crystalline material. The classical definition of “void” in a crystalline material refers to small regions where there are no atoms, and can be thought of as clusters of vacancies. In the present disclosure, this definition is extended to include all the crystalline structures mentioned above and within this invention, such as the hollow space within nanotubes, nanocubes, nanoballs and fullerenes.

The term “nanotube” refers to a tubular-shaped, molecular structure generally having an average diameter in the inclusive range of 25 Å to 500 nm, such as from 1 nm to 100 nm. Lengths of any size may be used.

The term “carbon nanotube” or any version thereof refers to a tubular-shaped, molecular structure composed primarily of carbon atoms arranged in a hexagonal lattice (a graphene sheet) which closes upon itself to form the walls of a seamless cylindrical tube. These tubular sheets can either occur alone (single-walled) or as many nested layers (multi-walled) to form the cylindrical structure.

The term “confined” are any version thereof (e.g., “confinement”, “confining”, etc), refers to the sequestering of a fluid, e.g., gas or liquid, at elevated pressures. In contrast, the term “storage” refers to an equilibrium distribution of relatively low pressure fluid in or around the crystalline void structure.

The term “functionalized” (or any version thereof) refers to a nanotube having an atom or group of atoms attached to the surface that may alter the properties of the nanotube.

The term “doped” carbon nanotube refers to the presence of ions or atoms, other than carbon, into the crystal structure of the rolled sheets of hexagonal carbon. Doped carbon nanotubes means at least one carbon in the hexagonal ring is replaced with a non-carbon atom.

The term “plasma” refers to an ionized gas, and is intended to be a distinct phase of matter in contrast to solids, liquids, and gases because of its unique properties. “Ionized” means that at least one electron has been dissociated from a proportion of the atoms or molecules. The free electric charges typically make the plasma electrically conductive so that it responds strongly to electromagnetic fields.

An “aligned array” refers to an arrangement of carbon nanotubes grown to give one or more desired directional characteristics. For example, an aligned array of surface grown carbon nanotubes typically, but not exclusively, comprise random or ordered rows of carbon nanotubes grown substantially perpendicular to the growth substrate.

The terms “nanostructured” and “nano-scaled” refers to a structure or a material which possesses components having at least one dimension that is 100 nm or smaller. A definition for nanostructure is provided in The Physics and Chemistry of Materials, Joel I. Gersten and Frederick W. Smith, Wiley publishers, pp. 382-383, which is herein incorporated by reference for this definition.

The phrase “nanostructured material” refers to a material whose components have an arrangement that has at least one characteristic length scale that is 100 nanometers or less. The phrase “characteristic length scale” refers to a measure of the size of a pattern within the arrangement, such as but not limited to the characteristic diameter of the pores created within the structure, the interstitial distance between fibers or the distance between subsequent fiber crossings. This measurement may also be done through the methods of applied mathematics such as principle component or spectral analysis that give multi-scale information characterizing the length scales within the material.

“Chosen from” or “selected from” as used herein refers to selection of individual components or the combination of two (or more) components. For example, the nano-structured material can comprise carbon nanotubes that are only one of impregnated, functionalized, doped, charged, coated, and irradiated nanotubes, or a mixture of any or all of these types of nanotubes such as a mixture of different treatments applied to the nanotubes.

### B. Embodiments

In one embodiment, there is disclosed a method for the sequestering of volatile materials, which comprises confining at least one volatile material inside a substantially single crystalline void structure. This crystalline confinement structure is comprised of at least one substantially closed wall structure, such that it acts as a pressure vessel. In another embodiment, the crystalline confinement vessel has at least one dimension on the nanoscale, such as a nanotube.

With respect to the crystalline structures, they may be made from inorganic materials. In one embodiment, such materials include traditional single crystalline and polycrystalline bulk materials chosen from silicon, carbon, boron, boride, silicide, carbide, oxide, nitride or their combinations.

The crystalline structures may also be made from advanced materials, such as nanowires, nanoribbons, nanotubes, nanocubes, nanoballs and nano fullerenes. Any combinations of the materials and structures disclosed herein are within the scope of the present invention, such as single-walled carbon nanotubes (SWCNTs) and multi-walled carbon nanotubes (MWCNTs).

In one embodiment, the crystalline void structure comprises graphene nano-tubes, graphene meso-tubes, graphene micro-tubes, graphene nano-spheres, graphene meso-spheres, micro-spheres, diamond nano-tubes, diamond meso-tubes, diamond micro-tubes, diamond nano-spheres, diamond meso-spheres, and diamond -spheres

The crystalline confinement vessel may also contain at least one valve structure sufficient to substantially confine the fluid within the void(s). If present, the valve is sufficient to maintain mechanical integrity of the crystalline confinement vessel, even if a pressure or chemical gradient exists between the internal and external environments of the crystalline structure. For example, a crystalline confinement vessel according to the present disclosure is capable of maintaining mechanical integrity despite the gradient between the high pressure on the interior surface of the vessel and the lower or even ambient pressure on the exterior surface.

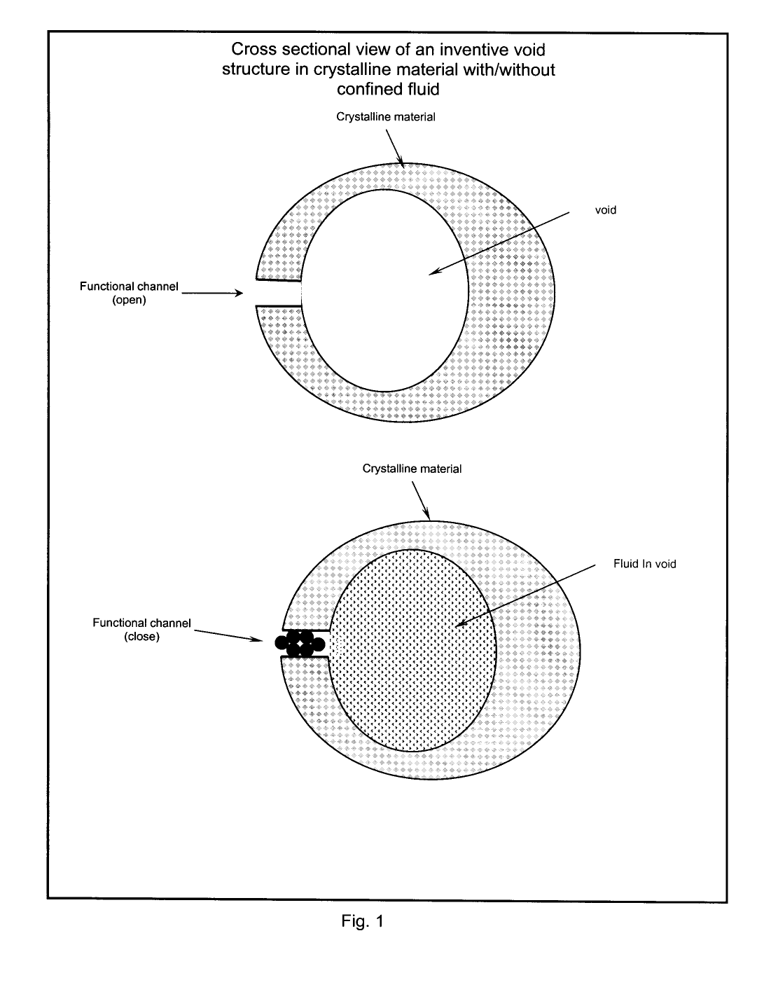

In one embodiment, the void in the crystalline materials could be accessible from outside of the crystalline material through a functional channel The so called functional channel is a channel that can be changed from being in a substantially open or permeable state to a substantially close or impermeable state controlled by physical, chemical and electrochemical signals. Selective materials, such as titanium, nickel, tin, chromium, palladium, platinum, gold, ruthenium, iridium, carbon, silicon, or their alloys and compounds could be incorporated to the channel achieving the above mentioned functionality. To achieve different functionality over the channel for the confinement of different fluid, different types of substances could be chosen and it might not be limited to the above mentioned chemical elements (shown in FIG. 1).

The valve structure disclosed herein may use thermal, mechanical, or chemical dynamics to switch from a substantially open or permeable state to a substantially closed or impermeable state. For example, in one embodiment, a valve may simply be composed of palladium. At one temperature the palladium is permeable to hydrogen. At a sufficiently lower temperature the palladium is substantially impermeable to the diffusion of hydrogen, and thus can sufficiently maintain mechanical integrity between the internal volume and the external volume.

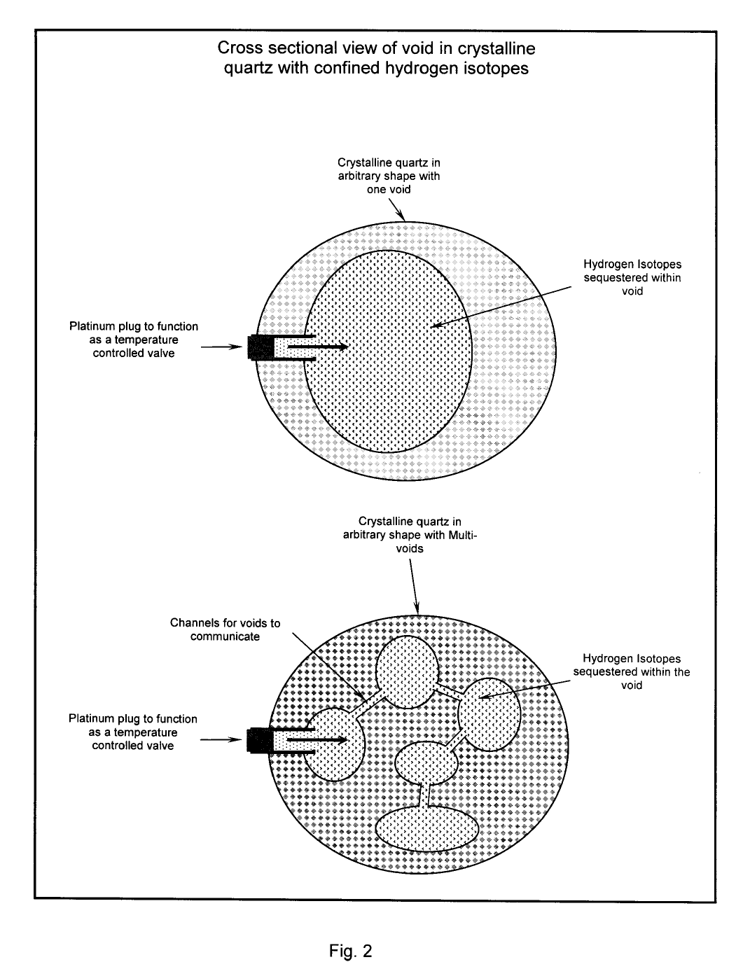

The valve structure may depend on the crystal lattice for structural support. As shown in FIG. 2, a palladium plug at the end of a carbon nanotube may act as a temperature dependent valve. A valve constructed in this way, however, may depend on the strength of the graphene lattice used to form the crystal lattice. Thus, depending on the pressure range to be confined, the carbon nanotube may be specifically tailored, for example from a thin-walled cylinder made of single walled carbon nanotubes, to a thicker-walled cylinder made of multi-walled carbon nanotubes. It is to be appreciated that while mention is made to carbon nanotubes, any form of nanotube, even non-carbon, made be used.

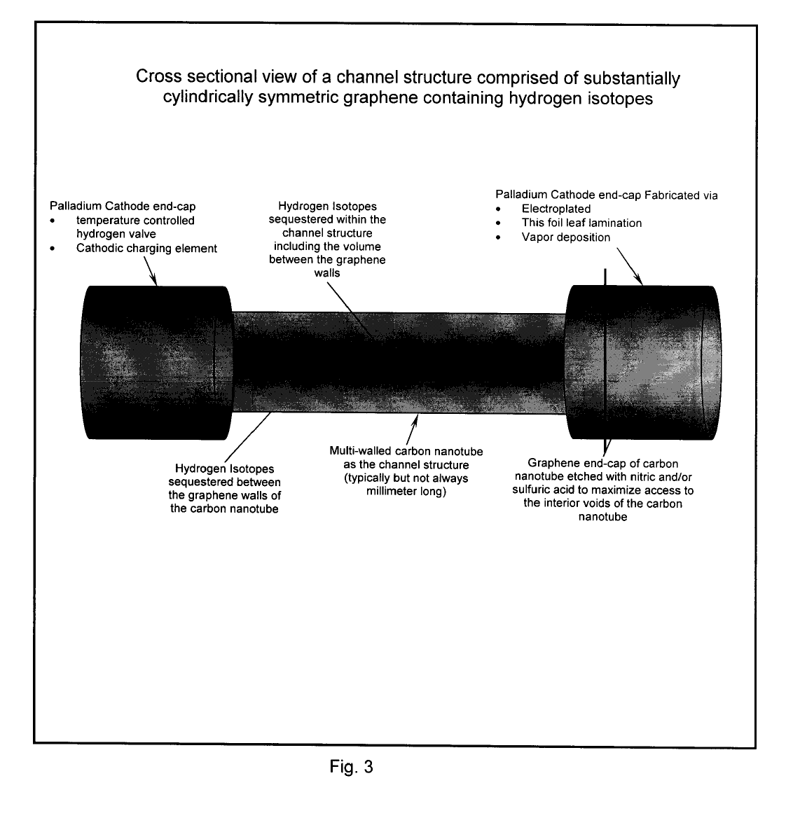

With the voids and controlled functionally channel, many kinds of fluids could be confined into the disclosed article, they could be in the state of gas, a liquid, a supercritical fluid and a plasma. They could also be any of the materials from the list of: fuels, inorganic solvents, organic solvents, acids, bases, alcohols, oxidizing agents, polymers, proteins, fusible isotopes, fissionable isotopes, molten metals, drugs, isotopes of hydrogen, helium, lithium, boron, nitrogen, oxygen, carbon, fluorine, bromine, lithium, sodium, uranium, beryllium, calcium, cesium, rubidium, palladium, iodine, plutonium, strontium. Compounds of the above mentioned chemical elements might also be confined in the voids. Such embodiments are shown in FIGS. 2 and 3.

Non-limiting examples of the gases that may be confined according to the present disclosure include hydrogen isotopes, oxygen isotopes, or other oxidizing agents and combinations thereof. In addition, the source of hydrogen isotopes may be in a solid, liquid, gas, plasma, supercritical phase. Alternatively, the source of hydrogen isotopes may be bound in a molecular structure.

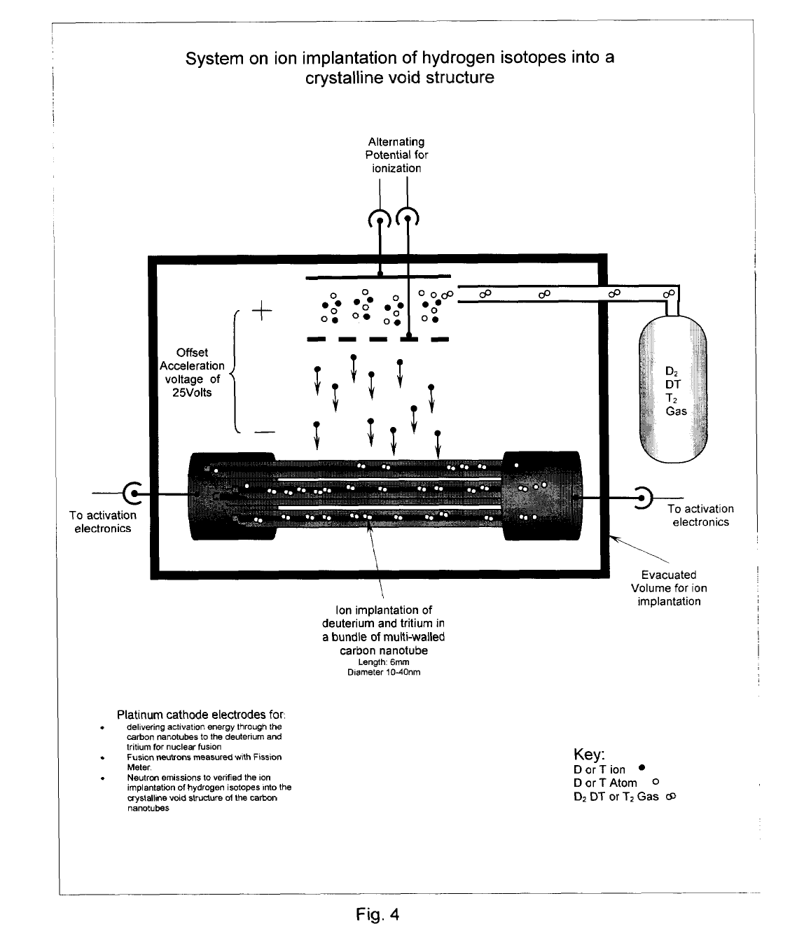

As stated, the fluids disclosed herein could be captured and released from the void in a crystalline structure by physical, chemical and electrochemical techniques, which can be chosen from cathodic charging, ion implantation (FIG. 4), electrophoresis, pressure gradients flow dynamics, mechanical pump, micro or molecular pump. In one embodiment, the fluid can be released on demand and used to initiate and sustain a chemical, electrochemical biological or nuclear reaction.

There is also disclosed a method of releasing gas from the crystalline voids for consumption, such as the release of hydrogen for combustion with oxygen in a fuel cell. Alternatively, the hydrogen may be consumed within the crystalline void structure resulting in the release of energy.

In one embodiment, the disclosed method may also be used for the confinement of high pressure solvents such that the crystalline void structure is both the containment vessel and the reaction vessel. For example, reagents, solvated in supercritical CO₂, may be combined in ways not yet possible, or even forbidden by classic chemical techniques.

In one embodiment, the hydrogen isotopes of deuterium and tritium may sequestered in the crystalline void structure to be utilized in the production of nuclear fusion energy.

The void volume described herein is the volume defined by the inside edge of the innermost layer of cylinder, such as the carbon or graphene tube. In one embodiment, the volatile material is comprised of hydrogen isotopes, confined inside a carbon nanotube with the assistance of a valve in the form of a palladium plug that is held at a low temperature to maintain a sufficiently low diffusion of the hydrogen isotopes. In this embodiment, the crystalline void structure is used to confine the volatile hydrogen isotopes in the form of a nano-confinement fusion crucible. Such an embodiment may be used for hydrogen nuclear fusion reactions.

In another embodiment, pump devices may be mechanically integrated into the crystalline void structure to drive a pressure gradient.

In one embodiment, cathodic charging is used to fill and pressurize a crystalline void structure with hydrogen. Cathodic charging of hydrogen is accomplished by embedding hydrogen into an appropriate cathode during the electrolysis of water. For example, palladium is an appropriate cathode material and is the ideal material for the valve structure due to the temperature dependent diffusivity of palladium.

In another embodiment the crystalline void structure is comprised of carbon, silicon, titanium, boron, aluminum, zirconium, and oxides, borides, and nitrides thereof, alone or in combination.

In another embodiment the valve structure is comprised of palladium, platinum, gold, ruthenium, iridium, carbon, silicon, and combinations thereof.

In another embodiment the volatile materials that may be confined include, but are not limited to hydrogen, oxygen, fluorine, bromine, chlorine, lithium, sodium, carbon monoxide, carbon dioxide, water, acids, bases, organic solvents, polymers, proteins, and combinations thereof. Furthermore the volatile materials may be in the form of a gas, a liquid, a solid, an ionized plasmas, or a supercritical fluid.

In one embodiment, multiple valves structures are integrated into a serial structure together act to pump volatile materials to the required pressure within the crystalline void structure.

The nanotubes may be comprised of numerous materials, including metals and their oxides, inorganic materials, including glasses, carbon and its allotropes, compounds thereof, and all combinations thereof. In one embodiment, the crystalline void structure is substantially comprised of carbon and its allotropes, including graphene, diamond and combinations thereof.

Furthermore, the nanotubes may be formed into an aligned array, such as being aligned end to end, parallel, or in any combination thereof. In addition, or alternatively, the nanotubes may be fully or partially coated or doped by least one atomic or molecular layer of an inorganic material.

The nanotube structure disclosed herein may comprise single walled, double walled or multi-walled nanotubes or combinations thereof. The nanotubes may have a known morphology, such as those described in Applicants co-pending applications, including U.S. patent application Ser. No. 11/111,736, filed Apr. 22, 2005, U.S. patent application Ser. No. 10/794,056, filed Mar. 8, 2004 and U.S. patent application Ser. No. 11/514,814, filed Sep. 1, 2006, all of which are herein incorporated by reference.

Some of the above described shapes are more particularly defined in M. S. Dresselhaus, G. Dresselhaus, and P. Avouris, eds. Carbon Nanotubes: Synthesis, Structure, Properties, and Applications, Topics in Applied Physics. 80. 2000, Springer-Verlag; and “A Chemical Route to Carbon Nanoscrolls, Lisa M. Viculis, Julia J. Mack, and Richard B. Kaner; Science, 28 Feb. 2003; 299, both of which are herein incorporated by reference.

It is understood that the nanotube structure may comprise a network of nanotubes which are optionally in a magnetic, electric, or otherwise electromagnetic field. In one non-limiting embodiment, the magnetic, electric, or electromagnetic field can be supplied by the nanotube structure itself.

In addition, the method may further include applying an alternating current direct current or current pulses to the containment device or combinations thereof in order to pressurize the crystalline void structure with the volatile material.

The nanotube structure disclosed herein may have a epitaxial layers of metals or alloys. In one embodiment, the void in crystalline material disclosed herein may have epitaxial layers of metals or alloys on the exterior or interior of the said crystalline material. Non-limiting examples of such metals may be chosen from antimony, aluminum, zinc, gold, silver, copper, platinum, palladium, nickel, iridium, rhodium, cobalt, osmium, ruthenium, iron, manganese, molybdenum, tungsten, zirconium, titanium, gallium, indium, cesium, chromium, gallium, cadmium, strontium, rubidium, barium, beryllium, tungsten, mercury, uranium, plutonium, thorium, lithium, calcium, niobium, tantalum, tin, lead, or bismuth, yttrium for different applications. The metals or metal alloys may be deposited using traditional chemical and physical techniques. Non-limiting examples of these traditional methods are salt decomposition, electrolysis coating, electro-coating, precipitation, metal organic chemical vapor deposition, electron sputtering, thermal sputtering, and/or plasma assisted deposition.

In this embodiment the metal may be deposited using traditional chemical methods or chemical or physical vapor deposition methods. Non-limiting examples of traditional chemical methods are salt decomposition, electrolysis coating, electro-coating, precipitation, and colloidal chemistry. Non-limiting examples of chemical or physical vapor deposition methods are metal organic chemical vapor deposition, electron sputtering, thermal sputtering, and/or plasma sputtering.

The composition of the nanotube is not known to be critical to the methods described herein. Without being bound by theory, it appears that the volatile materials can be cathodically charged and confined within the carbon nanotube.

In addition, the morphology (geometric configuration) of the crystalline material, other than providing confinement for the volatile material, is not known to be critical. As previously stated, the thickness of the cylinder, determined by the number of walls in a nanotube, for example, would likely be determinative of the pressure that could be contained within the vessel. Thus, in addition to the use of single or multi-walled, carbon nanotubes, the nanotube structure disclosed herein may have single or multiple atomic or molecular layers forming a shell or coating on the nanotubes described herein. In addition to such coatings, the nanotube structure may be doped by least one atomic or molecular layer of an inorganic or organic material.

A description of coatings for nanotubes, as well as methods of coating nanotubes, are described in applicants co-pending application, which were previously incorporated by reference.

The method described herein may further comprise functionalizing the carbon nanotubes with at least one organic group. Functionalization is generally performed by modifying the surface of carbon nanotubes using chemical techniques, including wet chemistry or vapor, gas or plasma chemistry, and microwave assisted chemical techniques, and utilizing surface chemistry to bond materials to the surface of the carbon nanotubes. These methods are used to “activate” the carbon nanotube, which is defined as breaking at least one C-C or C-heteroatom bond, thereby providing a surface for attaching a molecule or cluster thereto.

Functionalized carbon nanotubes may comprise chemical groups, such as carboxyl groups, attached to the surface, such as the outer sidewalls, of the carbon nanotube. Further, the nanotube functionalization can occur through a multi-step procedure where functional groups are sequentially added to the nanotube to arrive at a specific, desired functionalized nanotube.

Furthermore, through the functinalization process it may be possible to attach valve and pump structures to the sidewalls of carbon nanotubes for the charging and containment of volatile materials.

Unlike functionalized carbon nanotubes, coated carbon nanotubes are covered with a layer of material and/or one or many particles which, unlike a functional group, is not necessarily chemically bonded to the nanotube, and which covers a surface area of the nanotube.

Carbon nanotubes used herein may also be doped with constituents to assist in the disclosed process. As stated, a “doped” carbon nanotube refers to the presence of ions or atoms, other than carbon, into the crystal structure of the rolled sheets of hexagonal carbon. Doped carbon nanotubes means at least one carbon in the hexagonal ring is replaced with a non-carbon atom.

The present disclosure is further illustrated by the following non-limiting example, which is intended to be purely exemplary of the disclosure.

### EXAMPLE

### Example 1

### Carbon Nanotubes Crystalline Void Structures Containing Cathodically Charged Deuterium

In this example the nanotubes were commercially pure carbon nanotubes obtained from NanoTechLabs (NanoTechLabs Inc., 409 W. Maple St., Yadkinville, N.C. 27055). They had a length of approximately 6 mm, with a 6 member ring structure and were generally straight in orientation. The carbon nanotubes were substantially defect free and were not treated prior to use in the device.

A bundle of aligned carbon nanotubes containing approximately 1,000 individual nanotube was connected to platinum electrodes at each end of the bundle. The carbon nanotube electrode system was measured to have approximately 8Ω of resistance. One nanotube electrode was connected through a capacitor to ground. The other nanotube electrode was connected through a transistor to ground. A third electrolysis electrode was held in close proximity to the center of the carbon nanotube bundle as was connected to a 490V 5 mA power supply through a 6KΩ resistor. A schematic and description of this set-up is shown in FIG. 3.

The carbon nanotube electrode system was submerged in 2 grams of liquid D₂O in a ceramic reactor boat at room temperature and pressure. A voltage was applied to the carbon nanotubes as a 490 Volt spike for a duration in the range of from 10 to 100 nanoseconds at a repetition rate of approximately 730 Hz. During the millisecond the capacitor was charging, the charging current was also used to perform electrolysis of the D₂O to produce cathodically charged carbon nanotubes

Neutron bursts 10,000 times above background were produced from deuterium confined inside the crystalline void structure of the carbon nanotubes when a current pulse was applied. Without being bound to theory it is believed that due to high local temperatures within the carbon nanotubes structural integrity was lost and the nanotubes detached from the platinum electrodes no longer made contact.

Prior to the application of the voltage two arrays of Germanium neutron detectors, placed on either side of the apparatus, were calibrated to determine the background rate of neutrons at the site of the experiment. The detectors were state of the art neutron detectors that were the property of the Lawrence Livermore National Laboratories and the manner in which the detectors operated was proprietary to their owners.

The data generated from this example was statistically analyzed via a Hurst analysis to determine the statistical significance of the results. A Hurst analysis is a correlated analysis of random and non-random occurrences of events yielding a figure of merit. A figure of merit centered around 0.5 indicates random data. A figure of merit approaching 1.0 indicates positive correlation. A figure of merit approaching zero indicates anti-correlation. Data according to this example approached 0.9 indicating high positive correlation. In other words, the statistical analysis of the data from this example provides strong evidence of cathodicly charged crystalline void structures with an isotope of hydrogen.

Unless otherwise indicated, all numbers expressing quantities of ingredients, reaction conditions, and so forth used in the specification and claims are to be understood as being modified in all instances by the term “about.” Accordingly, unless indicated to the contrary, the numerical parameters set forth in the following specification and attached claims are approximations that may vary depending upon the desired properties sought to be obtained by the present invention.

Other embodiments of the invention will be apparent to those skilled in the art from consideration of the specification and practice of the invention disclosed herein. It is intended that the specification and examples be considered as exemplary only, with the true scope of the invention being indicated by the following claims.

What is claimed is:

1. A method for loading and confining a volatile material inside of a substantially crystalline void structure, said method comprising:
a) transmitting said volatile material through an open or permeable portion of a crystalline void structure; and
b) confining said volatile materials inside said substantially crystalline void structure by closing said open portion with a valve or rendering said permeable portion impermeable to said volatile material.

2. The method of claim 1, wherein the said valve is comprised of at least one defect in the said crystalline structure, a crystalline valve structure, a semi permeably material, a one way valve, a ball valve, or combinations thereof.

3. The method of claim 2, wherein the said valve can change from being in a substantially open or permeable state to a substantially closed or impermeable state controlled by temperature, pressure, memory effects, chemical reactions, mechanical motion, electric fields, magnetic fields, or combinations thereof.

4. The method of claim 1, wherein the crystalline void structure may be used for a pressure vessel, a temperature and pressure regulated reaction vessel or combinations thereof.

5. The method of claim 1, wherein the said volatile material is in a state comprising a gas, a liquid, a solid, a supercritical fluid, a plasma, or any combination thereof.

6. The method of claim 1, wherein the said crystalline void structure is comprised of polycrystalline material, a single crystalline material, or layered combinations thereof.

7. The method of claim 1, wherein the said volatile materials are comprised of fuels, inorganic solvents, organic solvents, acids, bases, alcohols, oxidizing agents, polymers, proteins, fusable isotopes, fissionable isotopes, molten metals and combinations thereof.

8. The method of claim 1, wherein the said volatile materials comprise isotopes of hydrogen, helium, lithium, boron, nitrogen oxygen carbon, fluorine, bromine, and combinations thereof.

9. The method of claim 1, wherein said valve is comprised of a palladium plug, and the crystalline void structure is comprised of a carbon cylinder or tube.

10. The method of claim 1, further comprising:
confining hydrogen,
releasing said hydrogen,
combining said released hydrogen with oxygen in a fuel cell to generate electric energy.

11. The method of claim 1, wherein said crystalline void structure further comprises a pump containing sufficient mechanically integrated to drive a pressure gradient between the inner and outer surfaces of said crystalline void structure.

12. The method of claim 1, wherein said volatile material is driven into said crystalline void structure by at least one method chosen from cathodic charging, ion implantation, electrophoresis, pressure gradients flow dynamics, or combinations thereof.

13. The method of claim 1, wherein said crystalline void structure is comprised of carbon, graphene, diamond, silicon, quartz, titanium oxide, boron, silicon carbide, and combination thereof.

14. The method of claim 1, wherein the said valve structure is comprised of palladium, platinum, gold, ruthenium, iridium, carbon, silicon, and combinations thereof.

15. The method of claim 1, wherein the volatile materials are comprised of hydrogen, oxygen, fluorine, bromine, chlorine, lithium, sodium, carbon monoxide, and carbon dioxide.

16. The method of claim 1, wherein said crystalline void structure is comprised of graphene nano-tubes, graphene meso-tubes, graphene micro-tubes, graphene nano-spheres, graphene meso-spheres, micro-spheres, diamond nano-tubes, diamond meso-tubes, diamond micro-tubes, diamond nano-spheres, diamond meso-spheres, and diamond -spheres.

17. The method of claim 1, wherein said crystalline void structure comprises single walled, double walled, or multi-walled nanotubes, and combinations thereof.

18. A method of generating a reaction using a volatile material inside of a substantially crystalline void structure, said method comprising:
a) transmitting said volatile material through an open or permeable portion of a crystalline void structure;
b) confining said volatile materials inside said substantially crystalline void structure by closing said open portion with a valve or rendering said permeable portion impermeable to said volatile material;
c) releasing said confined volatile material from said crystalline void structure; and
d) optionally combining said released volatile material with a different material to initiate or sustain a chemical, thermal, nuclear, electrical, mechanical, or biological reaction.

19. The method of claim 18, wherein said volatile material is hydrogen and said different material is oxygen.

20. The method of claim 18, wherein said volatile material comprises a hydrogen isotope from deuterium or tritium, that is released in an amount sufficient to initiate or sustain a nuclear reaction.

21. An article for the confinement of a fluid comprising one or more voids in a crystalline structure for confining said fluid, wherein the majority of the said voids have as a smallest dimension of one micron or less.

22. The article of claim 21, wherein said crystalline structure is an inorganic material comprising silicon, carbon, boron, boride, silicide, carbide, oxide, nitride or combinations thereof.

23. The article of claim 22, wherein said carbon is comprised of graphite, diamond or combinations thereof.

24. The article of claim 21, wherein said crystalline structure is comprised of single crystalline material, polycrystalline material or combinations thereof, that are in the shape of cylinder, tube, cone, cube or sphere.

25. The article of claim 24, wherein said tube is comprised of single walled, double walled, or multi-walled nanotubes, or combinations thereof.

26. The article of claim 21, wherein said one or more voids has at least one channel connecting the interior to the exterior of said crystalline structure.

27. The article of claim 26, wherein said channel comprises one or more functional groups attached thereto or located therein, wherein said functional groups comprise inorganic materials, organic moieties or combinations thereof.

28. The article of claim 27, wherein said inorganic material is chosen from titanium, nickel, tin, chromium, palladium, platinum, gold, ruthenium, iridium, carbon, silicon, or their alloys and compounds.

29. The article of claim 21, wherein said fluid comprises a gas, a liquid, a supercritical fluid, a plasma, or combinations thereof.

30. The article of claim 21, wherein said fluid is comprised of fuels, inorganic solvents, organic solvents, acids, bases, alcohols, oxidizing agents, polymers, proteins, fusible isotopes, fissionable isotopes, molten metals, drugs or combinations thereof.

31. The article of claim 21, wherein said fluid is includes isotopes of hydrogen, helium, lithium, boron, nitrogen, oxygen, carbon, fluorine, bromine, lithium, sodium, uranium, beryllium, calcium, cesium, rubidium, palladium, iodine, plutonium, strontium or combinations thereof.

32. The article of claim 31, wherein said hydrogen isotopes comprise deuterium and tritium.

33. The article of claim 21, were said one or more voids further comprise at least one epitaxial layer of metal on the exterior or interior of said crystalline material, wherein said metal is chosen from antimony, aluminum, zinc, gold, silver, copper, platinum, palladium, nickel, iridium, rhodium, cobalt, osmium, ruthenium, iron, manganese, molybdenum, tungsten, zirconium, titanium, gallium, indium, cesium, chromium, gallium, cadmium, strontium, rubidium, barium, beryllium, tungsten, mercury, uranium, plutonium, thorium, lithium, calcium, niobium, tantalum, tin, lead, or bismuth, yttrium or alloys of thereof.

34. The method of claim 1, further comprising depositing at least one epitaxial layer of metal or alloys on the exterior or interior of said crystalline material, wherein said metal is chosen from antimony, aluminum, zinc, gold, silver, copper, platinum, palladium, nickel, iridium, rhodium, cobalt, osmium, ruthenium, iron, manganese, molybdenum, tungsten, zirconium, titanium, gallium, indium, cesium, chromium, gallium, cadmium, strontium, rubidium, barium, beryllium, tungsten, mercury, uranium, plutonium, thorium, lithium, calcium, niobium, tantalum, tin, lead, or bismuth, yttrium or alloys of thereof.

35. The method of claim 34, wherein said epitaxial layer is deposited using a chemical or physical technique chosen from salt decomposition, electrolysis coating, electro-coating, precipitation, colloidal chemistry, metal organic chemical vapor deposition, electron sputtering, thermal sputtering, and/or plasma assisted deposition.
